(19) United States
(12) Patent Application Publication
(10) Pub. No.: US 2024/0339494 A1
(43) Pub. Date: Oct. 10, 2024

(54) VERTICAL MOSFET WITH HIGH SHORT CIRCUIT WITHSTAND TIME CAPABILITY

(71) Applicant: MaxPower Semiconductor, Inc., San Jose, CA (US)

(72) Inventors: Mohamed Darwish, Campbell, CA (US); Jun Zeng, Torrence, CA (US)

(73) Assignee: MaxPower Semiconductor, Inc., San Jose, CA (US)

(21) Appl. No.: 18/625,100

(22) Filed: Apr. 2, 2024

Related U.S. Application Data
(60) Provisional application No. 63/458,008, filed on Apr. 7, 2023.

(51) Int. Cl. H01L 29/06; H01L 29/78

(52) U.S. Cl. CPC H01L 29/0611; H01L 29/7813; H01L 29/7832

(57) ABSTRACT

A vertical MOSFET has an N-type drift layer over an N+ substrate. A horizontal JFET layer overlies the drift layer, where the JFET layer has P-type gate regions and N-type channel regions. A first N-type layer overlies the JFET layer. A P-type well layer overlies the first N-type layer. Gate trenches are formed through the P-type well layer and into the first N-type layer. N-type source regions abut the top areas of the gate trenches, and a source electrode contacts the source regions. The JFET N-type channel regions are generally directly below the gate trenches for conducting a vertical current when the MOSFET is in an on state. The source electrode is electrically connected to the JFET P-type gate regions via a deep P-type contact region. The JFET N-type channel regions pinch off during short circuit high current conditions to limit drain current.

### CROSS-REFERENCE TO RELATED APPLICATIONS

This application claims priority to provisional application Ser. No. 63/458,008, having a filing date of Apr. 7, 2023, by Mohamed Darwish et al.

### FIELD OF THE INVENTION

This invention relates to vertical power MOSFETs and, in particular, to techniques for increasing their short circuit withstand time (SCWT) capability.

### BACKGROUND

Power MOSFETs are widely used as switching devices in many electronic applications. It is desirable that power MOSFETs have both low power losses and high reliability.

FIG. 1 is a cross-section of one type of conventional MOSFET 10.

Over an N+ substrate 12 is grown an N-epitaxial drift layer 14. A P-type well 16 is then formed by ion implantation and thermal anneal or drive-in. N+ source regions 18 and P+ contact regions 20 are also formed by implantation and drive-in. A trenched gate 22 is then formed. The gate 22 has a gate oxide layer 24, and the etched trench is filled with doped polysilicon 26. An insulation layer 28 is formed over the gate 22. A metal source electrode 30 and a metal drain electrode 32 are then formed.

Such trenched-gate power MOSFETs, using semiconductor materials such silicon or silicon carbide (SiC), suffer from high electric fields at the bottom of the gate trench corners. To alleviate this problem, several structures were proposed to shield the gate 22 from the high electric field. In many applications, such motor drives, high short circuit current withstand capability is also required. Under short circuit (SC) test conditions, the device is subjected to both high voltage and high current for stress intervals with the gate turned on.

The MOSFET 10 of FIG. 1 has a relatively low short circuit current withstand time capability, and the thin gate oxide is susceptible to damage under high electric fields.

Accordingly, what is needed is a new MOSFET design that has significantly higher short circuit current withstand capability, compared to the MOSFET 10 of FIG. 1, and can withstand higher electrical fields without damage.

### SUMMARY

New vertical MOSFET structures and their methods of fabrication are disclosed. The new MOSFET structures provide significant performance and reliability advantages. The disclosed structures have a higher short circuit withstand time (SCWT) capability, a lower electric field at the gate trench (by shielding the gate trench oxide), and a lower specific on resistance (Rsp) for the same breakdown voltage, compared to conventional trench-gate MOSFETs such as shown in FIG. 1.

In one embodiment of the invention, an n-channel MOSFET basic cell structure has top, middle, and bottom portions. It is assumed that the starting substrate wafer is N+ silicon. The cells are formed in a cellular grid or in parallel stripes.

The top portion is formed in an epitaxial layer grown over the substrate. The top portion includes one or more trenched gates and also includes one or more second trenches formed during the same process steps used to form the gates. The gates and second trenches contain conductive electrodes such as highly doped polysilicon. The gates and second trench electrodes are surrounded by a thin gate oxide. The second trench electrodes are connected to the source metal, while the gate electrodes are connected to a gate pad.

The top portion also includes N+ source regions, P-wells, and P+ contact regions for the P-well connected to the source metal. The gate trenches and second trenches extend through the P-well and into an N-epitaxial layer.

The second trenches are surrounded by a deep, heavily doped P-type contact region.

The middle portion forms a long-channel JFET that includes P-type JFET gate regions separated by N-type JFET channel regions. The channel regions are directly below the gate trenches. The gate trench has a depth that is less than the top of the P-type JFET gate regions.

The gate trench is vertically separated from the P-type JFET gate regions by a distance d. The distance d and doping density in the N-epitaxial layer between the gate trench and the P-type JFET gate regions are optimized to shield the gate trench oxide from high electric fields under reverse bias conditions and allow unimpeded current flow from the gate to the drain when the device is on. The P-type JFET gate regions are heavily doped such that they are not fully depleted under reverse bias, where the integrated areal charge for the P-type JFET gate regions is higher than 2e12 cm⁻² for silicon or 2e13 cm⁻² for silicon carbide (SiC). The N-type JFET channel regions between the P-type JFET gate regions are fully depleted under reverse bias, where the integrated areal charge of the N-type JFET channel regions is equal to or less than 2e12 cm⁻² for silicon or 2e13 cm⁻² for silicon carbide (SiC).

The P-type JFET gate regions are connected together and are connected to the source metal at certain locations via the P+ contact region surrounding the second trenches. There may be a connection to the source metal at distributed locations in the cell array.

The bottom portion forms a thick N-drift layer grown over the N+ substrate, connected to the metal drain electrode.

Under short circuit conditions, as the drain current and voltage increase, the N-type JFET channel pinches-off, and the drain current saturates to effectively limit the short circuit current flow. As a result, the MOSFET structure has significantly lower saturation current (Idsat) compared to the conventional MOSFET due to the JFET effect. The JFET effect self-limits the increase in drain current while the drain voltage keeps increasing and significantly increases the device's short circuit (SCWT) capability. The ratio of the JFET's length vs. width (L/W) is selected to achieve a JFET I-V characteristic needed to meet the required Idsat and low output conductance characteristics.

Furthermore, under reverse bias, the voltage drops substantially across the JFET and the N-type drift layer, and there is only a small voltage drop across the top MOSFET portion. This allows forming a high density of trench gates with short MOSFET channel length (<0.25 um), which results in lower specific on-resistance. In addition, the P-type JFET gate regions shield the gate trench bottom and protects the gate oxide by reducing the electric field.

Other embodiments are disclosed.

### BRIEF DESCRIPTION OF DRAWINGS

FIG. 1 is a cross-section of a single cell in a conventional vertical MOSFET.

FIG. 2 illustrates one embodiment of the invention, which adds a horizontal series of JFETs under the trenched gates.

FIG. 3 is a Vds vs Ids graph for the MOSFET of FIG. 2.

FIG. 4 is similar to FIG. 2 but with the second trench extending into a P-type JFET gate region.

FIG. 5a illustrates the use of thicker gate oxide at the bottom of the trenches for higher voltage withstand capability.

FIGS. 5b and 5c illustrate variations in the depths of the second trenches.

FIG. 6 is similar to FIG. 5a but with the second trench having a uniform oxide thickness.

FIG. 7 illustrates the use of a split trench gate to reduce gate-drain capacitance, where the bottom portion of the gate is connected to the source metal. An alternative structure utilizes split-poly for both gate and second trenches.

FIG. 8 is a top-down view of a stripe-cell layout, with the P-type JFET gate regions between the trench gate strips. A group of four strips is surrounded by a single second trench and a deep P+ contact region (connected to the source metal).

FIG. 9 is a top-down view of a grid layout, with the P-type JFET gate regions forming a grid and where the trench gates are formed over the openings in the grid. A group of cells is surrounded by a single second trench and a deep P+ contact region (connected to the source metal).

FIGS. 10a-10j illustrate process steps for forming the MOSFET embodiment of FIG. 2.

Elements labeled with the same numerals in the various figures may be the same or similar.

### DETAILED DESCRIPTION

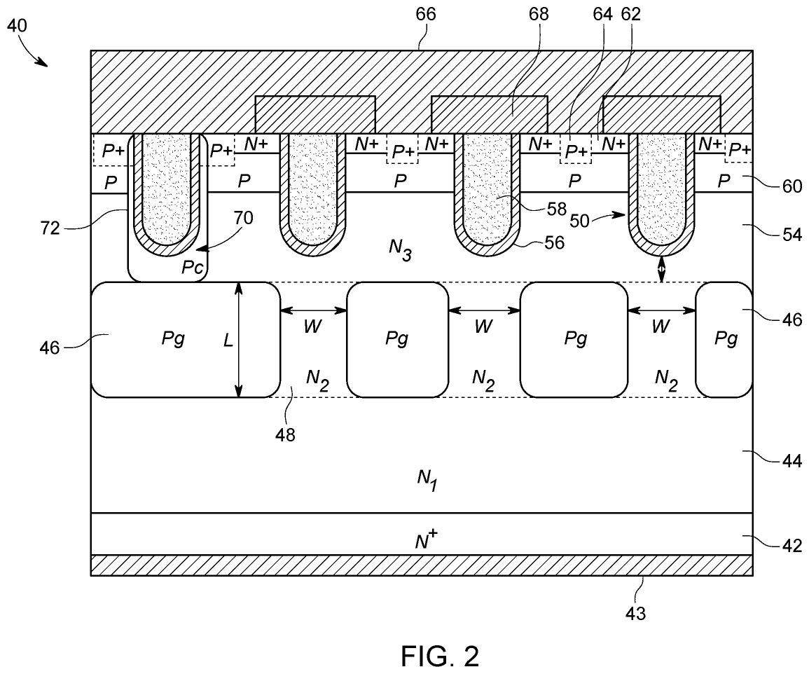

FIG. 2 illustrates a vertical MOSFET 40 in accordance with one embodiment of the invention. Only a small portion of the full MOSFET is shown, where the portion is repeated over a die area.

The starting substrate 42 is N+ and may be silicon, SiC, or other suitable semiconductor material. A metal drain electrode 43 is formed on the bottom of the substrate 42.

Epitaxially grown over the substrate 42 is a relatively thick N-type layer, where the bottom portion forms a drift region 44, with a lower dopant density of N1.

A middle portion may be formed by epitaxial growth followed by ion implantation and thermal anneal. The middle portion forms a long-channel JFET that includes P-type JFET gate regions (Pg) 46, having depth L and separated by N-type JFET channel regions 48 with a dopant density of N2. The width of the channel regions 48 is W. The gate trenches 50 have a depth that is shallower than the top of the JFET gate regions 46. The gate trenches 50 are vertically separated from the JFET gate regions 46 by a distance d.

The upper portion includes an N-type layer 54 with a dopant density of N3. The distance d and N3 dopant density are optimized to shield the gate trench oxide 56 from high electric fields under reverse bias conditions and allow unimpeded vertical current flow from the gate areas to the drain when the device is on. The dopant concentration of the N-type layer 54 will typically be higher than that of the much thicker N-type drift region 44 for a low on-resistance.

The JFET gate regions 46 are heavily doped such that they are not fully depleted under reverse bias, where the integrated areal charge is higher than 2e12 cm⁻² for silicon or 2e13 cm⁻² for silicon carbide (SiC). Whereas the integrated areal charge of the JFET channel regions 48 is equal to or less than 2e12 cm⁻² for silicon or 2e13 cm⁻² for silicon carbide (SIC).

The N-type JFET channel regions 48 are formed directly below the gate trenches 50, so the vertical current (when the gates are positively biased) generally flows along the inverted channel area along the gate trenches 50 and through the N-type JFET channel regions 48. The channel regions 48 may have a dopant concentration N2 that is higher than the dopant concentration N1 of the drift region 44. The N-type JFET channel regions 48 are doped to be fully depleted under reverse bias. Furthermore, to obtain the best long channel JFET characteristics, the ratio of the JFET channel region 48 length L to its width W should be greater than 2 [i.e., (L/W)>2].

The top portion of the MOSFET 40 includes the gate trenches 50, the gate oxide 56, and conductive doped polysilicon 58 in the trenches 50. A P-well 60 is formed by ion implantation and drive-in. Top N+ source regions 62 are formed along with P+ contact regions 64. The source regions 62 and the contact regions 64 contact the metal source electrode 66. The gate polysilicon 58 is insulated from the source electrode 66 by an oxide portion 68.

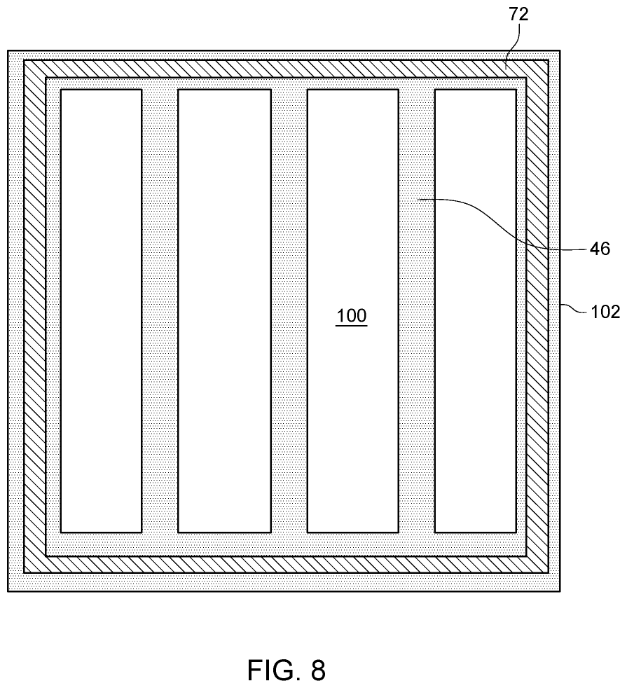

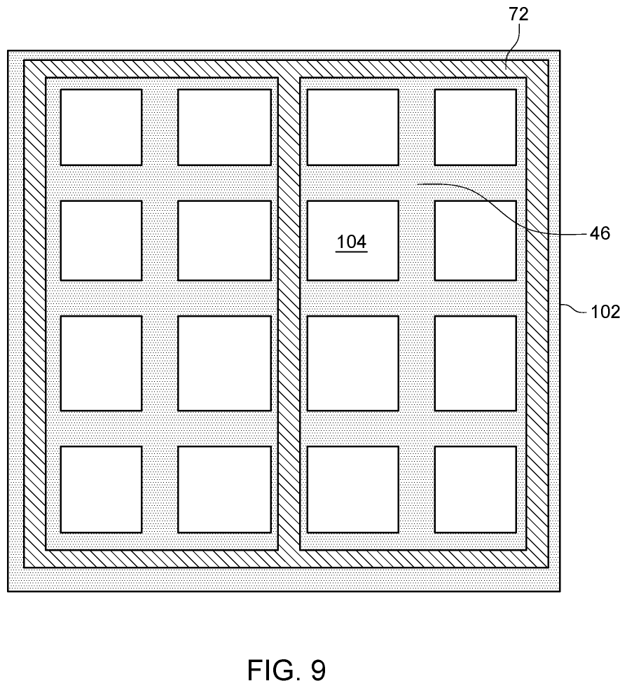

One of the trenches in the group of cells is a second trench 70, formed at the same time as the gate trenches 50. The second trench 70 does not have source regions abutting it. The polysilicon 58 in the second trench 70 contacts the source electrode 66, so the second trench 70 does not create an inversion layer when the device is on. A heavily doped P-type contact region 72 around the second trench 70 forms a contact region for the P-type JFET gate regions 46, to cause all the JFET gate regions 46 to be electrically connected to the source electrode 66 and to the P-well 60. All the JFET gate regions 46 are connected together within the N-type epitaxial layer. FIGS. 8 and 9 show possible layouts for the P-type JFET gate regions.

The connection of the JFET gate regions 46 to the source electrode 66 and P-well 60 via the P-type contact 72 region is only in certain areas necessary for proper operation of the JFET. In one embodiment, the second trench 70 surrounds a group of active cells, such as eight cells.

The second trench 70 is considered self-aligned to the gate trench since it is formed at the same time as the gate trenches 50. In an alternative structure, a deep ion implant may be used to form the P-type contact region 72 without forming the second trench 70.

When a positive voltage is coupled to the drain electrode 43 and a load (connected to ground) is coupled to the source electrode 66, current flows vertically through the MOSFET when the gate polysilicon 58 is biased above the threshold voltage to create a conducting inversion layer along the sides of the gate trenches 50. The current flows through the N-type channel regions 48 of the JFET. Under normal conditions, the voltage of the P-type JFET gate regions 46 is somewhat lower than the voltage in the N-type JFET channel region 48.

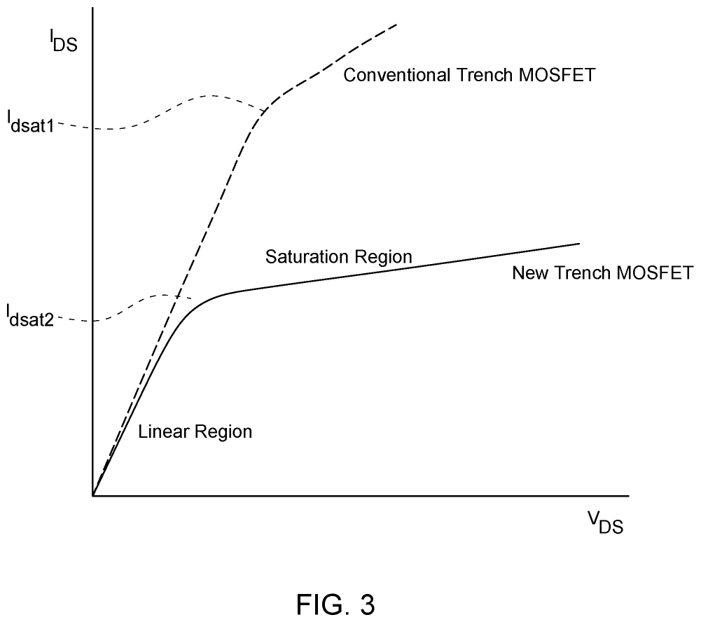

Under high current, short circuit conditions, as the drain current and drain-source voltage significantly increase, the N-type JFET channel regions 48 pinch-off, due to the JFET gate regions 46 having a lowered bias voltage (the source voltage) compared to the voltage in the channel region 48. This causes the drain current to saturate (Idsat2) and be limited, where the JFET enters the saturation region shown in the I-V graph of FIG. 3.

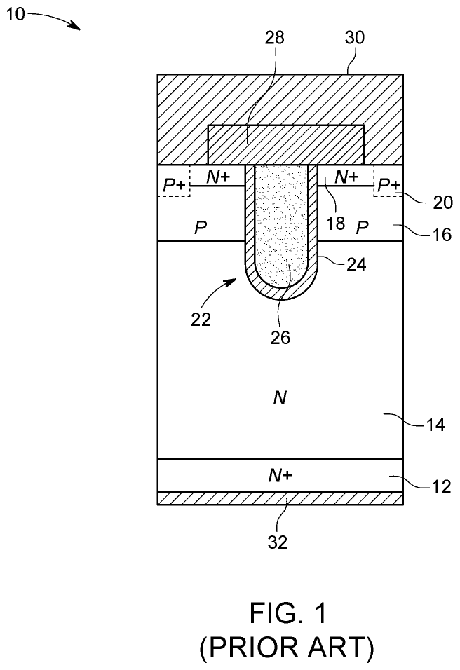

FIG. 3 is a current vs voltage (I-V) graph showing the drain-source current IDS VS. drain-source voltage VDs of the new MOSFET design compared to the conventional MOSFET design of FIG. 1. The new MOSFET structure has significantly lower saturation current Idsat2 compared to the conventional MOSFET Idsat1 due to the JFET effect. The JFET effect self-limits the increase in drain current while the drain-source voltage keeps increasing and significantly increases the device's short circuit withstand time (SCWT) capability.

The ratio of (L/W) in the JFET is important to achieve the long channel JFET I-V characteristics to meet the required Idsat and low output conductance characteristics.

Furthermore, under reverse bias conditions, the voltage drops substantially across the JFET and drift layer 44, and there is only a small voltage drop across the top MOSFET portion. This allows forming a high density of gate trenches 50 with short MOS channel length (<0.25 um), which results in lower specific on-resistance. In addition, the JFET gate regions 46 shield the gate trench bottom and protects the gate oxide 56 by reducing the electric field around the gate oxide 56.

FIG. 2 shows the JFET gate region 46 below the second trench 70 larger than the other JFET gate regions 46, but this is not required.

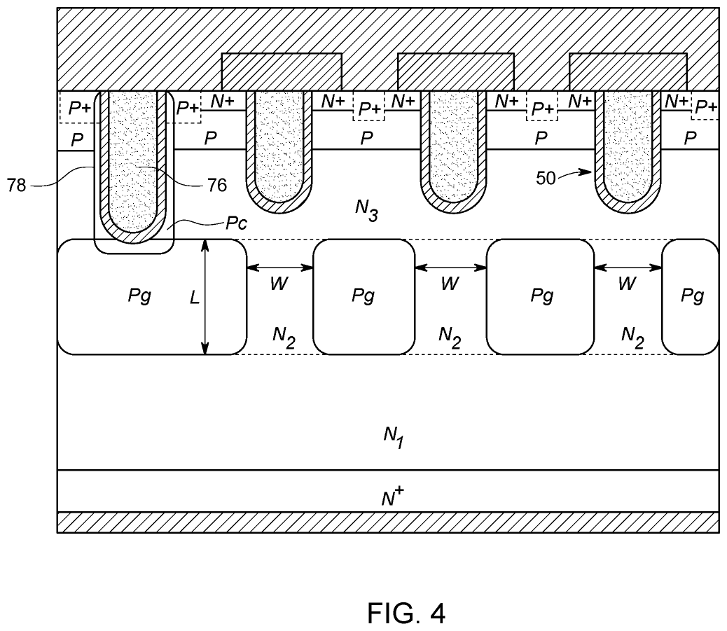

FIG. 4 shows another embodiment similar to that shown in FIG. 2 but with the second trench 76 deeper than the gate trenches 50. This may reduce the resistance of the P-type contact region 78, since the P-type implant for forming the P-type contact region 78 is through the second trench 76 prior to the polysilicon deposition.

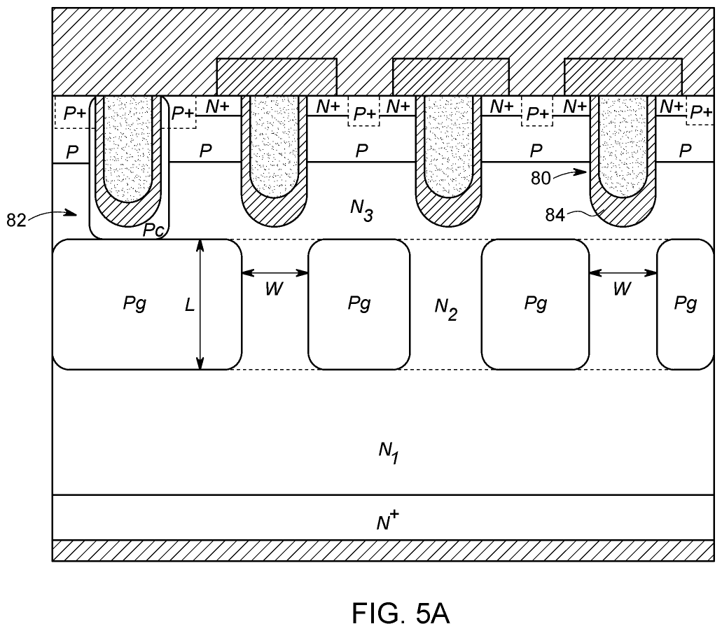

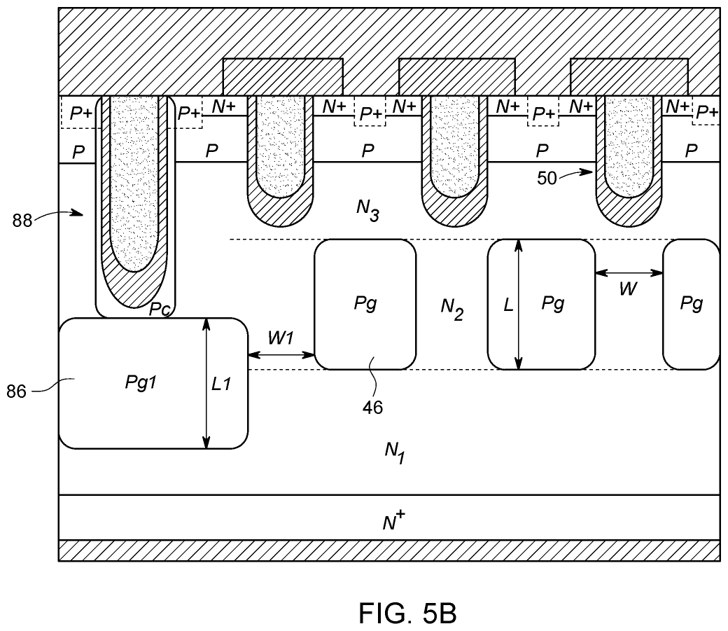

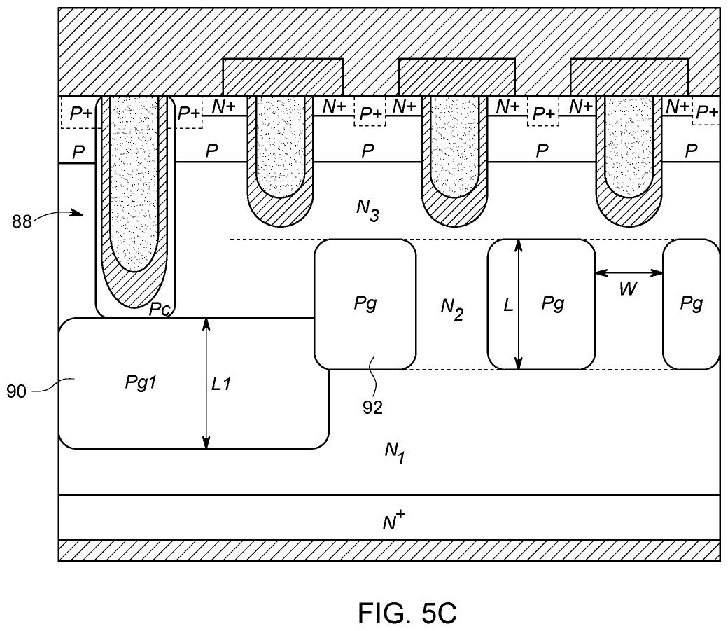

FIG. 5a shows another embodiment similar to that shown in FIG. 2 but where both the gate trenches 80 and the second trench 82 have a thicker bottom oxide layer 84 to reduce the gate-drain capacitance Cgd or gate-drain charge Qgd.

FIG. 5b shows another embodiment similar to that shown in FIG. 5a but with the JFET gate region 86 under the second trench 88 being lower than the JFET gate regions 46 under the gate trenches 50. The JFET channel length L1 and width W1 can be the same or different from L and W in FIG. 4. This may be done to make the currents associated with each gate trench 50 more uniform to avoid hot spots.

FIG. 5c shows another embodiment similar to that shown in FIG. 5b but with the JFET gate region 90 below the second trench 88 overlapping the adjacent JFET gate region 92.

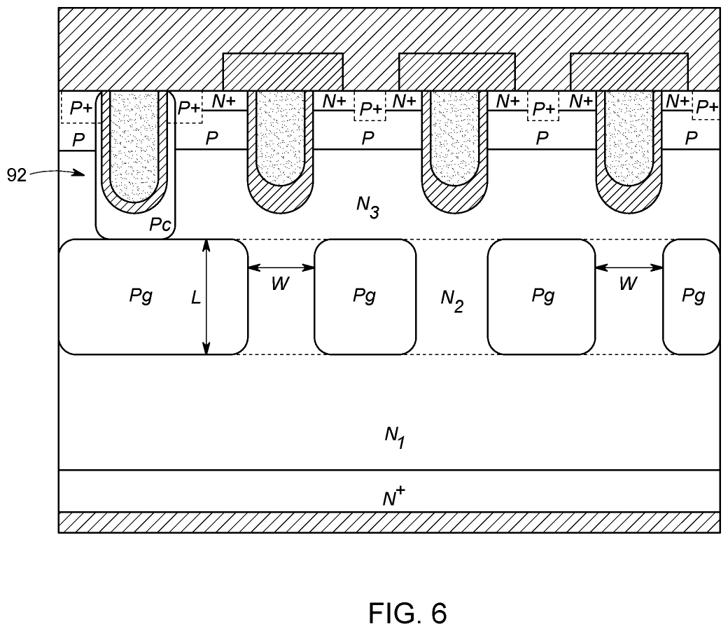

FIG. 6 shows another embodiment similar to that shown in FIG. 5a but with the second trench 92 having a uniform oxide thickness.

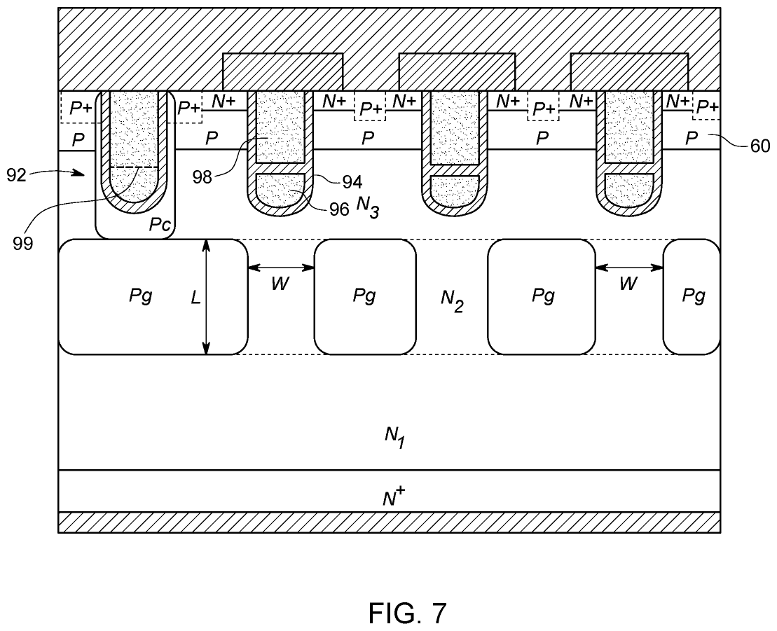

FIG. 7 shows another embodiment similar to that shown in FIG. 2 but with the gate electrode (polysilicon) being a split gate to reduce Cgd. An oxide layer 94 separates the polysilicon in each gate. The lower portion 96 of the split gate is preferably connected to the source electrode (out of the plane of FIG. 7). The upper portion 98 of the gate, when positively biased, inverts the P-well 60 near the gate trenches to conduct a vertical current.

In another embodiment, the second trench 92 is also split by an oxide layer 99.

FIG. 8 is a top-down view of a small portion of a P-type dopant implant mask for the P-type JFET gate region doping. FIG. 8 illustrates a cell area that is repeated over the die area. The cells are connected in parallel. Note how the JFET gate regions 46 are all connected together. The P-type JFET gate regions 46 surround elongated gate trenches in the areas 100. The stripes may be much longer compared to their width. The JFET gate region 102 that is below the second trench 70 (FIG. 2) and P-type contact region 72 forms an outer perimeter for a group of gate trenches. The layout is sufficient to adequately bias the JFET gate regions 46 (with the source voltage) while using up only a small portion of silicon real estate for the second trenches 70.

FIG. 9 is similar to FIG. 8 but the layout forms square areas 104 of gate trenches surrounded by N+ source regions.

The doping levels and sizes of the various regions may be determined by simulation to achieve the desired MOSFET characteristics.

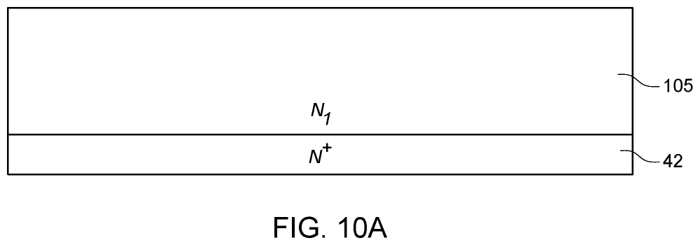

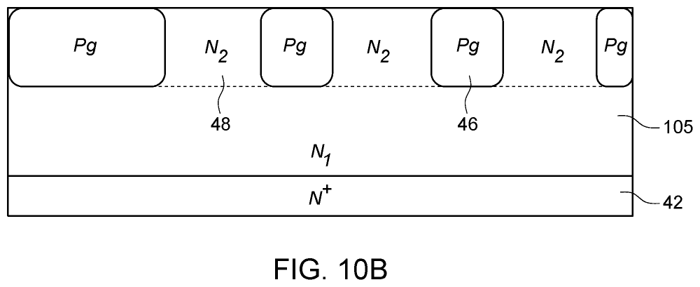

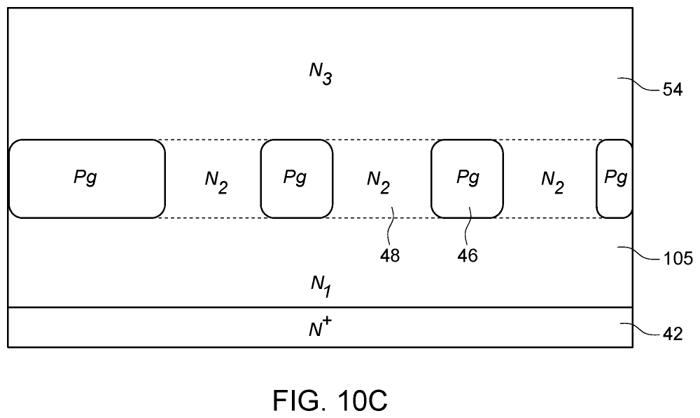

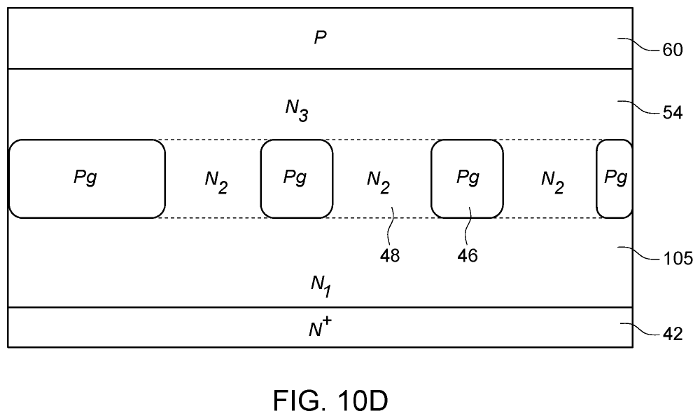

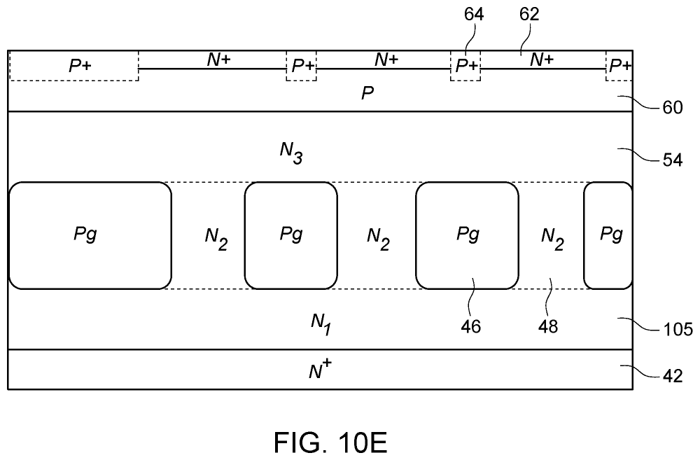

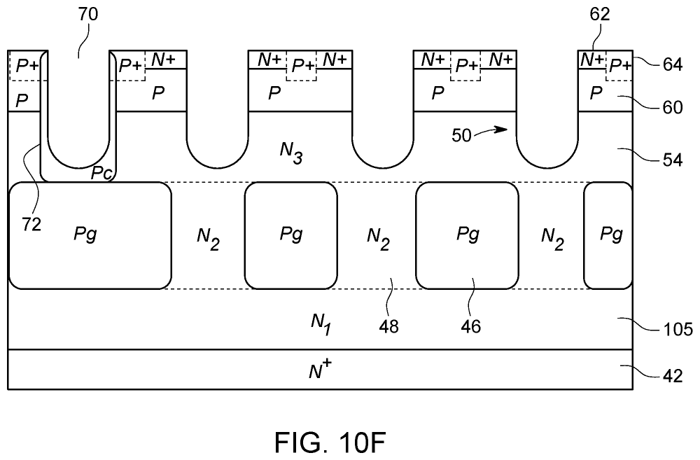

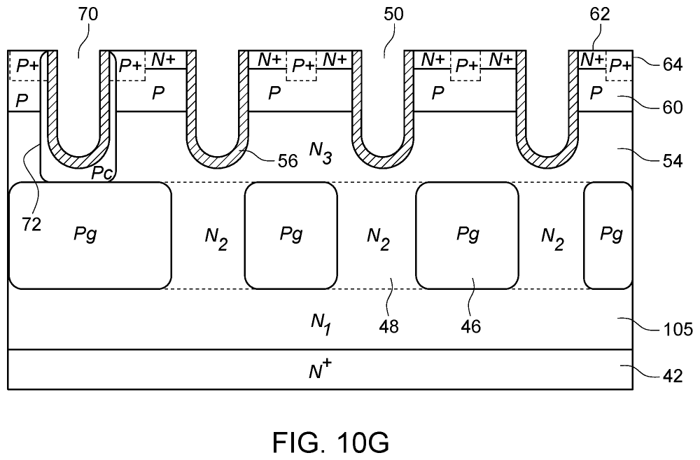

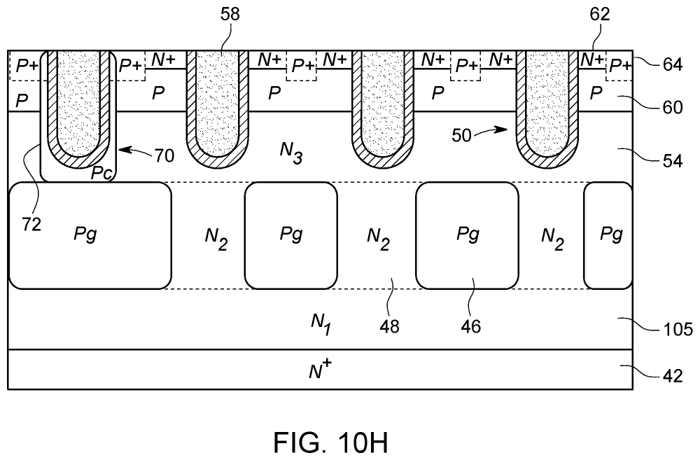

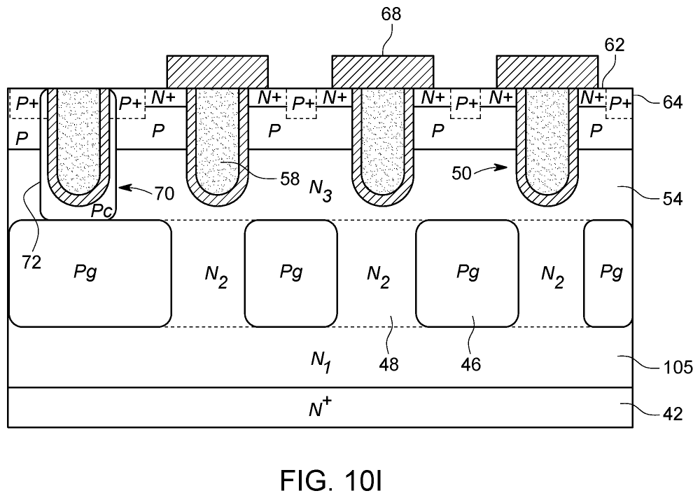

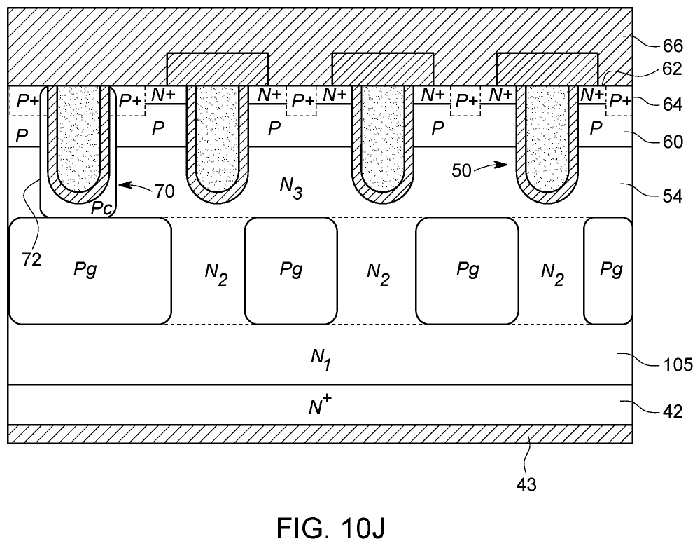

FIGS. 10a through 10j show an example of a fabrication method to manufacture the device shown in FIG. 2.

FIG. 10a shows an N-type epitaxial layer 105, with dopant concentration N1, grown over the N+ substrate 42.

FIG. 10b shows the P-type JFET gate regions 46 and the N-type channel regions 48, with a dopant concentration N2, formed in the epitaxial layer 105 by ion implantation. Alternatively, regions 46 and 48 are formed using epitaxial growth techniques.

FIG. 10c shows a subsequent epitaxial N-type layer 54, with dopant concentration N3, grown on top of the regions 46 and 48.

FIG. 10d shows the P-well 60 formed in the layer 54 by ion implantation.

FIG. 10e shows N+ source regions 62 and P+ contact regions 64 formed by ion implantation and drive-in.

FIG. 10f shows the gate trenches 50 and second trench 70 etched and also shows the P+ contact region 72 formed by ion implantation through the second trench 70.

FIG. 10g shows the gate oxide 56 grown inside the trenches.

FIG. 10h shows the trenches filled with doped polysilicon 58.

FIG. 10i shows an oxide 68 or other dielectric formed over the polysilicon 58 in the gate trenches 50.

FIG. 10j shows the metal source electrode 66 and the metal drain electrode 43 formed after the wafer is thinned from the bottom.

The specific electrical characteristics of devices fabricated using the methods described in this disclosure depend on a number of factors, including the thickness of the layers, their doping levels, the materials being used, the geometry of the layout, etc. One of ordinary skill in the art will realize that simulation, experimentation, or a combination thereof can be used to determine the design parameters needed to operate as intended.

The figures in this disclosure are not to scale but are qualitatively correct, and the geometries used in practice may differ and should not be considered a limitation in any way. It is understood by those of ordinary skill in the art that the actual layout will vary depending on the specifics of the implementation and any depictions illustrated herein should not be considered a limitation in any way.

It is also understood that numerous combinations of the above embodiments can be realized. All the above variants of the structure can be realized in stripe or cellular layout such as square, rectangular, hexagonal or circular layouts.

The new structures can be utilized using different semiconductor materials such as silicon, silicon carbide, etc. The dopant types can be reversed for a P-channel MOSFET.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A vertical MOSFET comprising:
a drift layer of a first conductivity type;
a JFET layer overlying the drift layer, the JFET layer comprising JFET gate regions of a second conductivity type and JFET channel regions of the first conductivity type;
a first layer of the first conductivity type overlying the JFET layer;
a well layer of the second conductivity type overlying the first layer;
source regions of the first conductivity type formed over the well layer;
gate trenches formed through the well layer and abutting the source regions;
a first electrode electrically contacting the source regions, the well layer, and the JFET gate regions; and
a second electrode electrically contacting the drift layer,
wherein the JFET channel regions are directly below the gate trenches for conducting a vertical current when the MOSFET is in an on state.

2. The MOSFET of claim 1 further comprising a contact region of the second conductivity type electrically connecting the first electrode to the JFET gate regions.

3. The MOSFET of claim 2 wherein the contact region surrounds a plurality of the gate trenches.

4. The MOSFET of claim 3 wherein the contact region surrounding the plurality of gate trenches is part of a single cell that is repeated across at least a portion of a die to form a plurality of cells connected in parallel.

5. The MOSFET of claim 2 wherein a non-gate trench surrounds the gate trenches, and the contact region surrounds the non-gate trench.

6. The MOSFET of claim 1 wherein the JFET layer is configured so that the JFET channel regions pinch off during short circuit conditions to limit current flow.

7. The MOSFET of claim 6 wherein the JFET enters saturation when a current through the MOSFET reaches a threshold current.

8. The MOSFET of claim 1 further comprising:
a non-gate trench surrounding a plurality of the gate trenches; and
a contact region of the second conductivity type surrounding the non-gate trench and extending down between the first electrode and the JFET gate regions to electrically connect the first electrode to the JFET gate regions.

9. The MOSFET of claim 8 wherein the non-gate trench has a same depth as the gate trenches.

10. The MOSFET of claim 8 wherein the non-gate trench is deeper than the gate trenches.

11. The MOSFET of claim 1 wherein the JFET gate regions form a grid, and a gate trench is formed in openings in the grid.

12. The MOSFET of claim 11 further comprising a contact region of the second conductivity type electrically connecting the first electrode to the JFET gate regions, wherein the contact region surrounds a plurality of JFET gate regions and gate trenches.

13. The MOSFET of claim 1 wherein the first conductivity type is N-type and the second conductivity type is P-type.

14. The MOSFET of claim 1 wherein the JFET channel regions are configured to fully deplete under reverse bias conditions of the MOSFET.

15. The MOSFET of claim 1 wherein the drift layer is more lightly doped than the first layer.
